(19) United States
(12) Patent Application Publication
(10) Pub. No.: US 2015/0048690 A1
(43) Pub. Date: Feb. 19, 2015

(54) MEDIUM VOLTAGE POWER CONTROLLER

(71) Applicant: SOLCON INDUSTRIES LTD., Yoqneam IIIit (IL)

(72) Inventors: Yoram WALTUCH, Haifa (IL); Meir BEN HAMO, Sde Yaakov (IL)

(73) Assignee: SOLCON INDUSTRIES LTD., Yoqneam IIIit (IL)

(21) Appl. No.: 13/967,361

(22) Filed: Aug. 15, 2013

(51) Int. Cl. H02J 3/00; H05K 7/20

(52) U.S. Cl. CPC H02J 3/00; H05K 7/20409; H05K 7/20154
USPC 307/112

(57) ABSTRACT

A power controller for controling power supply to a load at medium voltage is disclosed. The power controller may include a switching module electrically connected between a meduim voltage AC power supply and a load to switch on or to switch off power supply to the load. The power controller may also include a cooling system for cooling the switching module, and a control module to control the switching module by causing the switching module to operate under a switching scheme, wherein the switching scheme includes switching on and off for predetermined periods of time of varying durations.

### FIELD OF THE INVENTION

The present invention relates to power control. More specifically, the present invention relates to a system and method for power control operating at medium voltage.

### BACKGROUND OF THE INVENTION

Some electrical systems require power controllers to control the power supply to these systems. A power controller is designed to dictate the manner in which power from a power source (e.g., the mains power supply) is transferred to a load (e.g., motor, heating element, boiler, etc.).

For example, when an AC motor is operated at a medium voltage, a soft starter, which is a kind of a power controller, may be used. The soft starter is designed to prevent wear of the mains, motor and load caused by a sudden current surge, by initially providing reduced voltage to the motor and increasing the voltage over a predetermined time period, typically to a maximal level, so as to facilitate a “soft start” of the motor. Once the motor has properly started, the power for that motor is supplied directly (typically by providing a direct bypass connection overriding the soft starter).

In the context of the present specification, the term “medium voltage” is understood to refer to 1000V and above.

### SUMMARY OF THE INVENTION

There is thus provided, in accordance with some embodiments of the present invention, a power controller for controling power supply to a load at medium voltage. The power controller may include a switching module electrically connected between a meduim voltage AC power supply and a load to switch on or to switch off power supply to the load. The power controller may further include a cooling system for cooling the switching module. The power controller may also include a control module to control the switching module by causing the switching module to operate under a switching scheme, wherein the switching scheme includes switching on and off for predetermined periods of time of varying durations.

According to some embodiments, the switching module may include thyristors, and the control module may be configured to provide firing signals to switch the thyristors on and off.

In some embodiments, the thyristors comprise SCRs.

According to some embodiments, the SCRs may be arranged in one or a plurality of pairs, in opposing configuration.

In some embodiments, the coiling system may include one or a plurality of heat sinks.

According to embodiments, said one or a plurality of heat sinks may include cooling fins to allow air passing between the cooling fins to dissipate heat.

According to some embodiments, the heat sinks are made of aluminum.

In some embodiments, the cooling system may include fans.

According to some embodiments, the cooling system may include a plurality of fan units mounted on a rack and positioned adjacent to the switching module.

In some embodiments, the switching module may include a plurality of thyristors and wherein the rack is positioned adjacent to the thyristors.

In accordance with some embodiments of the present invention, there is provided a method of controlling medium voltage power supply to a load. The method may include electrically connecting a switching module between a meduim voltage AC power supply and the load to switch on or to switch off power supply to the load. The method may also include cooling the switching module using a cooling system. The method may further include using a control module, causing the switching module to operate under a switching scheme, wherein the switching scheme includes switching on and off for predetermined periods of time of varying durations.

### BRIEF DESCRIPTION OF THE DRAWINGS

In order for examples to be better illustrated, the following figures are provided and referenced hereafter. It should be noted that the figures are given as examples only and in no way limit the scope of the present disclosure. It will be appreciated that, for simplicity and clarity of illustration, elements shown in the figures have not necessarily been drawn to scale. For example, the dimensions of some of the elements may be exaggerated relative to other elements for clarity. Like components are denoted by like reference numerals.

FIG. 1 illustrates a schematic electric block diagram of a power controller, according to some embodiments of the present invention.

FIG. 2 illustrates a design for a switching device, for use in a power controller, according to some embodiments of the present invention.

FIG. 3A illustrates a fan assembly for use in a power controller according to some embodiments of the present invention.

FIG. 3B illustrates a fan unit of the fan assembly shown in FIG. 3A.

FIG. 4 illustrates a plot of a typical temperature vs. time in an operation scheme of a power controller designed to provide power to a heater.

FIG. 5 illustrates a control module of a power controller according to some embodiments of the invention.

### DETAILED DESCRIPTION OF THE INVENTION

In the following detailed description, numerous specific details are set forth in order to provide a thorough understanding of the methods and systems. However, it will be understood by those skilled in the art that the present methods and systems may be practiced without these specific details. In other instances, well-known methods, procedures, and components have not been described in detail so as not to obscure the present methods and systems.

Although the examples disclosed and discussed herein are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. Unless explicitly stated, the method examples described herein are not constrained to a particular order or sequence. Additionally, some of the described method examples or elements thereof can occur or be performed at the same point in time.

Unless specifically stated otherwise, as apparent from the following discussions, it is appreciated that throughout the specification, discussions utilizing terms such as “adding”, “associating” “selecting,” “evaluating,” “processing,” “computing,” “calculating,” “determining,” “designating,” “allocating” or the like, refer to the actions and/or processes of a computer, computer processor or computing system, or similar electronic computing device, that manipulate, execute and/or transform data represented as physical, such as electronic, quantities within the computing system's registers and/or memories into other data similarly represented as physical quantities within the computing system's memories, registers or other such information storage, transmission or display devices.

Some embodiments of the present invention are aimed at providing a power controller designed for controlling medium voltage power supply to a load over substantially extended periods of time (e.g. many minutes, hours, days, weeks, months, years, continuously). More objects and advantages will become apparent after reading the present specification and reviewing the appended figures.

Reference is made to the figures.

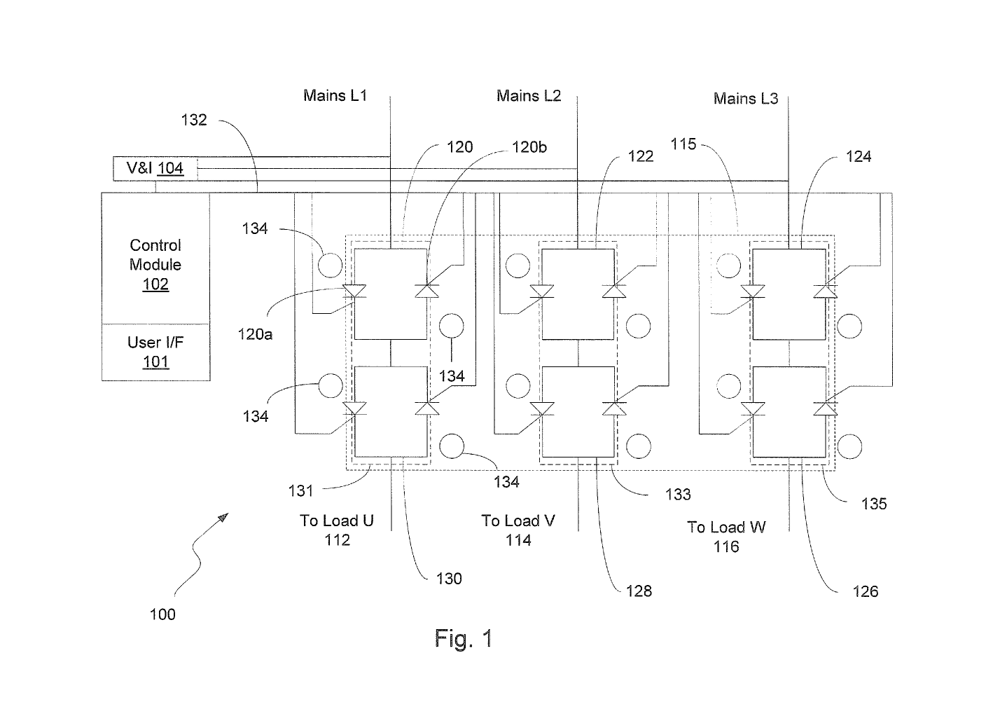

FIG. 1 illustrates a schematic electric block diagram of a power controller 100, according to some embodiments of the present invention.

In the example depicted in FIG. 1, the power controller 100 is designed to receive input power from a mains supply network that provides three phase input (L1, L2, L3), and is designed to provide power through three output bus bars or cables (U, V and W) to a load.

The load may be, for example, a single or a plurality of heating elements, e.g., an electric heater (for example, a furnace), operating at medium voltage.

The power control 100 includes a switching module 115 that includes a switching device for each input line (e.g. switching devices 131, 133 and 135 for lines L1, L2 and L3, respectively). Each of the switching devices includes one or a plurality of pairs of electronically controlled switching elements (such as thyristors—e.g., Silicon Controlled Rectifiers—SCRs, 120a, 120b, arranged in opposing configuration).

An SCR is a current controlling device, which in an “off” state allows only leakage current through. When applying a firing signal to the gate-to-cathode, that exceeds a threshold voltage value, the SCR turns “on” and conducts current through in a designated direction. The SCR remains conductive until the current drops below the holding current. The opposing configuration is designed to handle alternating current (AC), with each SCR of the pair handling one of the polarities (i.e., negative and positive).

The firing signals are provided and controlled by control module 102, which is configured to activate and operate the switching devices via line 132 in a predetermined switching scheme. Typically, the firing signals are transmitted via fiber optic wires. Control module 102 may be configured to sense voltage and current (V&I 104) for each of the input lines (L1, L2 and L3) and use this information for firing of the thyristors in a predetermined manner according to predefined setting of parameters of the control unit. Some physical parameters such as voltages, currents and power may also be displayed on a display device and may be transmitted over a communication link to another device (e.g., via serial link).

The power controller 100 is configured to operate over short or extended periods of time, e.g., for seconds, minutes, hours, days, months, weeks, and years, continuously.

As power controller 100 may operate at and is designed to deliver medium voltage, the switching devices (120, 122, 124, 126, 128, and 130) would heat up substantially. In order to cool the heated switching devices cooling devices, e.g., fans 134 are provided, placed adjacent to the switching devices, configured to operate continuously or at pre-designated times to blow ambient air at the SCRs to cool them.

In some embodiments of the present invention, the fans may be operated in various modes of operation. For example, the fans may be continuously or intermittently. In some embodiments a controller may activate the fans when a threshold temperature at or near the SCRs is reached and deactivate the fans when a lower temperature threshold is reached.

The cooling devices, according to some embodiments of the present invention, may include air cooling, liquid cooling), and may be, for example, fans, heat sinks, etc.

A user interface 101 may be provided to allow a user to input information and/or commands to a designated operation program run by the power controller.

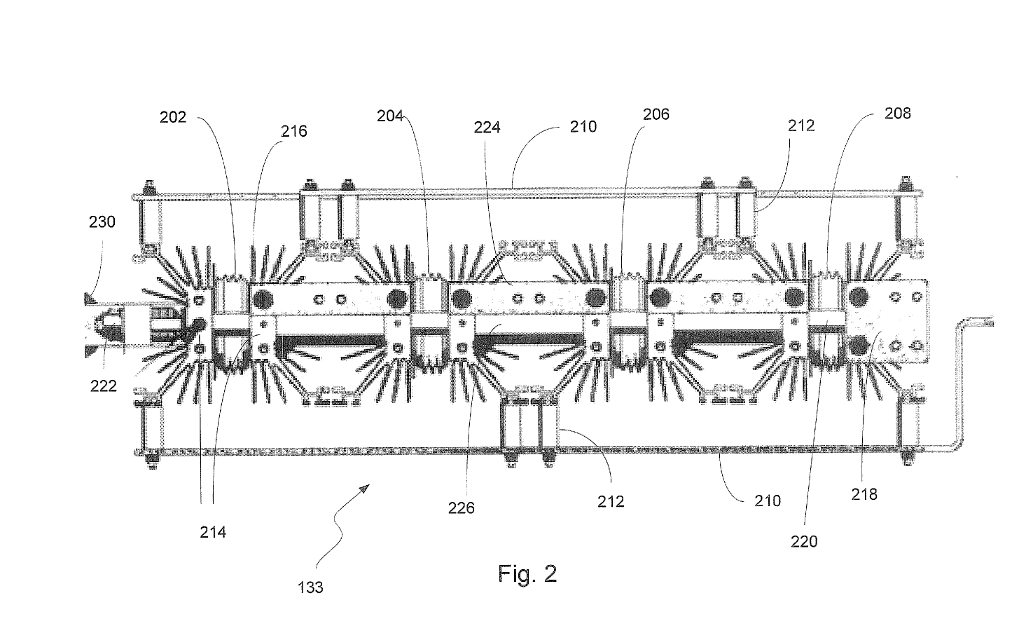

FIG. 2 illustrates a design for a switching device 133 (see also FIG. 1), for use in a power controller, according to some embodiments of the present invention.

Switching device 133 includes one or a plurality of pairs of SCRs—two in this example, where a first pair of SCRs, 202 and 204, and a second pair of SCRs 206 and 208 are provided. In each pair of opposing SCRs one SCR (202 and 208) is oriented to facilitate a flow of a current in one direction (one polarity of the AC) whereas the other SCR of the pair (204 and 206) is oriented to facilitate the flow of a current in the opposite direction (the opposite polarity of the AC). Lines 201 connect ports of the SCRs via connectors 212 to facilitate the opposite configuration. The SCRs (202, 204, 206 and 208) are all lined over bus bar 220, which is fixed at one end to base support 218 and fixed at an opposite end to anchoring support 230, tightened by nut 222.

SCRs 202, 204, 206 and 208 are separated by spacers 226, with each pair of adjacent SCRs being fastened together by fastening bars 224.

In some embodiments of the present invention, all the switching device elements other than the SCRs are made of a highly insulating material to withstand medium voltage and prevent undesired current leakage and partial discharge.

According to some embodiments of the present invention, each SCR comprises a base 214 which is made of good electrical and heat conductive material or materials, such as, for example, Molybdenum, and is designed to conduct electrical current and include a main body that acts as a heat-sink (e.g., an aluminium body). For example, the SCR may be provided with one or a plurality of heat-sink bodies 216 that may include cooling fins, so as to allow good heat dissipation.

In addition to or alternatively, fans may be used to cool the SCRs.

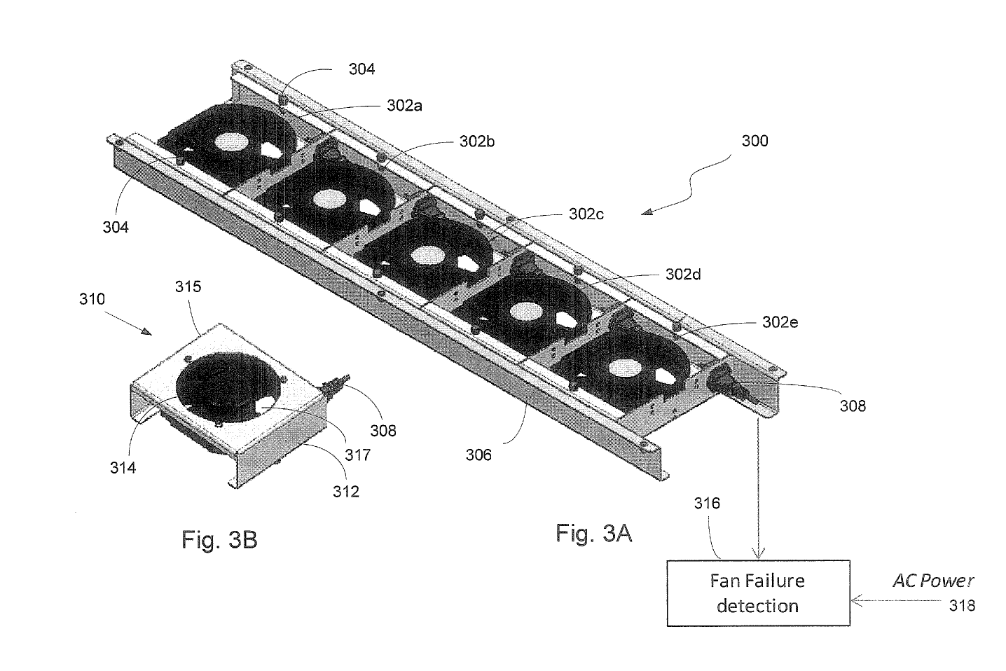

FIG. 3A illustrates a fan assembly 300 for use in a power controller according to some embodiments of the present invention. The fan assembly 300 may include a plurality of fan units 302a-302e, mounted on rack 306, fastened to rack 306 by screws 304, and arranged in a linear arrangement, matching the linear arrangement of the switching device (see FIG. 2). In this arrangement, the fan assembly may be placed next to the SCRs' heat sinks and blow cooling air on them during the operation of the switching device.

The fan units 302a-302e are typically electrically connected in parallel, via connectors 308.

FIG. 3B illustrates a fan unit 312 of the fan assembly shown in FIG. 3A.

Each fan unit may include a support sheet 315 provided with a hole 317 over which fan 314 is mounted.

Returning to FIG. 3A, the fan units 302a-302e are powered by an AC power input 318. A fan failure detection device 316 may be provided, which is capable of determining that any of the fans is malfunctioning by sensing changes in voltage or current through the fan units 302a-302e of the assembly 300.

Removing and replacing a malfunctioning fan unit may be accomplished easily by unscrewing and sliding out the malfunctioning fan unit from the rack and removing and replacing it with a properly functioning one.

An example of a power controller, according to some embodiments of the present invention, is a power controller for controlling power of a heater.

Operation times of a heater may vary (ranging from short spells of seconds and minutes to hours, days, weeks, months and even years, e.g., a furnace). A power controller according to some embodiments of the present invention may be used to control medium voltage power supply to the heater.

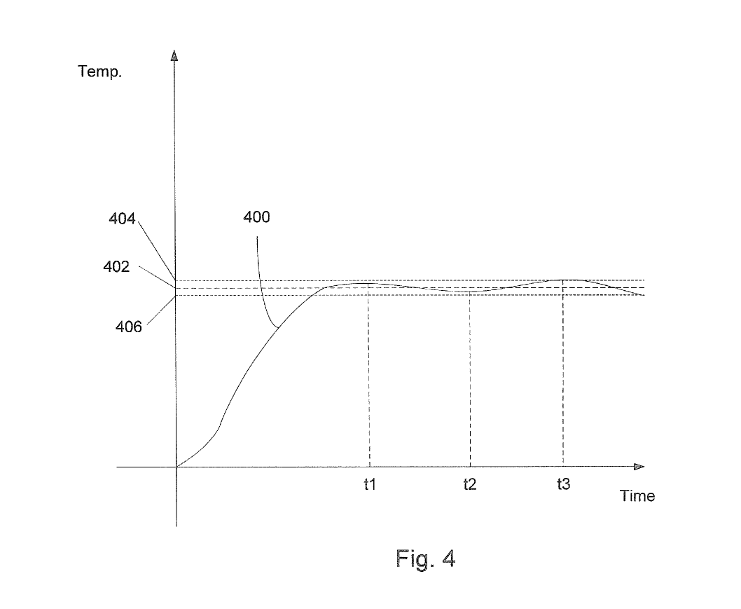

FIG. 4 illustrates a plot of temperature vs. time in an operation scheme of a power controller designed to provide power to a heater. For example, such a power controller may be designed to employ a switching scheme as follows: initially the power controller may cause the switching module to provide power to the heater for an extended period of time until temperature 400 of the heater reaches a desired predetermined upper threshold temperature 404. The temperature may be measured using an external or internal temperature controller When the temperature controller detects that the desired upper threshold temperature was reached (t1) the power controller causes the switching module to stop supplying power. As a result a temperature drop is sensed, which when reaching a predetermined lower threshold temperature 406 causes the power controller to cause the switching module to resume supplying power to the heater until the heater heats up to the upper threshold 404 temperature again. By selecting the upper and lower threshold temperatures (e.g., through the user interface 100, see FIG. 1, or by configuring the power controller accordingly) a user may determine a mean operating temperature 402 and set it to a desired level.

In some embodiments of the present invention phase control (power on-off occuring every half cycle of the mains power supply in each one of the phases), zero-crossing (power on off occurring once per several cycles of the mains power supply) operation methodology, or a combination between the two methods may be employed.

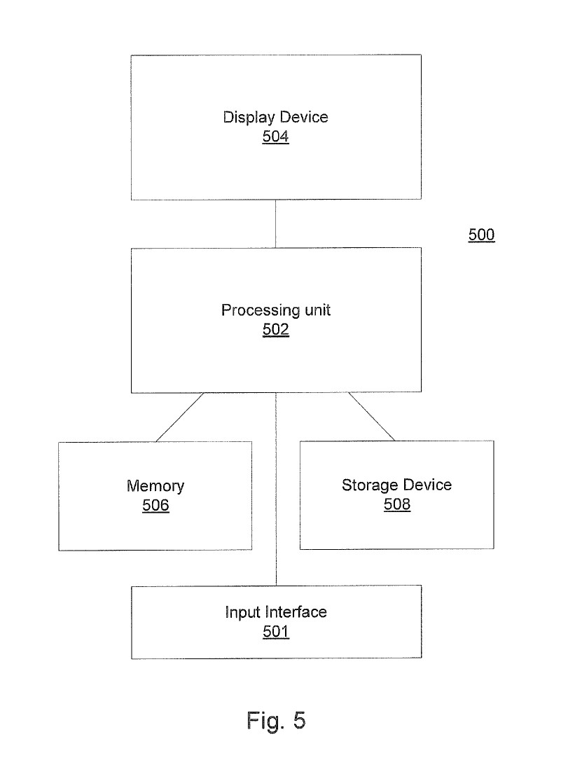

FIG. 5 illustrates a control module 500 for a power controller (see 102 in FIG. 1) according to some embodiments of the invention.

Control module 500 may include a processing unit 502 (e.g., one or a plurality of processors, on a single machine or distributed on a plurality of machines) for executing a method according to some embodiments. Processing unit 502 includes a memory 506 on which a program implementing a method according to examples and corresponding data may be loaded and run from, and storage device 508, which includes a non-transitory computer readable medium (or mediums) such as, for example, one or a plurality of hard disks, flash memory devices, etc. on which a program implementing a method according to examples and corresponding data may be stored, or which may be used as a recorder. Control module 500 may further include display device 504 (e.g., CRT, LCD, LED etc.) on which one or a plurality user interfaces associated with a program implementing a method according to embodiments of the present invention and corresponding data may be presented. Control module 500 may also include input device 501, such as, for example, one or a plurality of keyboards, pointing devices, touch sensitive surfaces (e.g., touch sensitive screens), etc. for allowing a user to input commands and data.

Some embodiments of the present invention may be embodied in the form of a system, a method or a computer program product. Similarly, examples may be embodied as hardware, software or a combination of both. Some embodiments of the present invention may be embodied as a computer program product saved on one or more non-transitory computer readable medium (or media) in the form of computer readable program code embodied thereon. Such non-transitory computer readable medium may include instructions that, when executed, cause a processor to execute method steps in accordance with some embodiments. In some embodiments, the instructions stores on the computer readable medium may be in the form of an installed application and in the form of an installation package.

Such instructions may be, for example, loaded by one or more processors and get executed.

For example, the computer readable medium may be a non-transitory computer readable storage medium. A non-transitory computer readable storage medium may be, for example, an electronic, optical, magnetic, electromagnetic, infrared, or semiconductor system, apparatus, or device, or any combination thereof.

Computer program code may be written in any suitable programming language. The program code may execute on a single computer system, or on a plurality of computer systems.

Some embodiments of the present invention are described hereinabove with reference to flowcharts and/or block diagrams depicting methods, systems and computer program products according to various embodiments.

Features of various embodiments discussed herein may be used with other embodiments discussed herein. The foregoing description of the embodiments has been presented for the purposes of illustration and description. It is not intended to be exhaustive or limiting to the precise form disclosed. It should be appreciated by persons skilled in the art that many modifications, variations, substitutions, changes, and equivalents are possible in light of the above teaching. It is, therefore, to be understood that the appended claims are intended to cover all such modifications and changes that fall within the true spirit of the disclosure.

1. A power controller for controling power supply to a load at medium voltage, the power controller comprising:
a switching module electrically connected between a meduim voltage AC power supply and a load to switch on or to switch off power supply to the load;
a cooling system for cooling the switching module; and
a control module to control the switching module by causing the switching module to operate under a switching scheme,
wherein the switching scheme includes switching on and off for predetermined periods of time of varying durations.

2. The power controller of claim 1, wherein the switching module comprises thyristors, and wherein the control module is configured to provide firing signals to switch the thyristors on and off.

3. The power controller of claim 2, wherein the thyristors comprise SCRs.

4. The power controller of claim 3, wherein the SCRs are arranged in one or a plurality of pairs, in opposing configuration.

5. The power controller of claim 1, wherein the coiling system comprises one or a plurality of heat sinks.

6. The power controller of claim 5, wherien said one or a plurality of heat sinks includes cooling fins to allow air passing between the cooling fins to dissipate heat.

7. The power unit of claim 6, wherein the thyristors and the heat sinks are made of aluminum.

8. The power controller of claim 1, wherien the cooling system comprises fans.

9. The power controller of claim 8, wherein the cooling system comprises a plurality of fan units mounted on a rack and positioned adjacent to the switching module.

10. The power controller of claim 9, wherein the switching module comprises a plurality of thyristors and wherein the rack is positioned adjacent to the thyristors.

11. A method of controlling medium voltage power supply to a load, the method comprising:
electrically connecting a switching module between a meduim voltage AC power supply and the load to switch on or to switch off power supply to the load;
cooling the switching module using a cooling system; and
using a control module, causing the switching module to operate under a switching scheme, wherein the switching scheme includes switching on and off for predetermined periods of time of varying durations.

12. The method of claim 11, wherein the switching module comprises thyristors, the method further comprising, using the control module, providing firing signals to switch the thyristors on and off.

13. The method of claim 12, wherein the thyristors comprise SCRs.

14. The method of claim 13, further comprising arranging the SCRs in one or a plurality of pairs, in opposing configuration.

15. The method of claim 11, wherein the coiling system comprises one or a plurality of heat sinks.

16. The method of claim 15, comprising providing cooling fins on said one or a plurality of heat sinks to allow air passing between the cooling fins to dissipate heat.

17. The method of claim 11, wherien the cooling comprises using fans.

18. The method of claim 17, further comprising providing a plurality of fan units mounted on a rack and positioning the rack adjacent to the switching module.

19. The method of claim 18, wherein switching module comprises a plurality of thyristors and wherein the method comprises positionign the rack adjacent to the thyristors.
